(19) United States
(12) Patent Application Publication
(10) Pub. No.: US 2015/0236567 A1
(43) Pub. Date: Aug. 20, 2015

(54) SECTIONED ELECTRICAL APPLIANCE ASSEMBLY

(71) Applicant: Wei-Lun Tseng, Taipei City (TW)

(72) Inventor: Wei-Lun Tseng, Taipei City (TW)

(21) Appl. No.: 14/251,590

(22) Filed: Apr. 12, 2014

(30) Foreign Application Priority Data
Feb. 20, 2014 (TW) 103202926

(51) Int. Cl. H02K 7/14; H05K 7/00

(52) U.S. Cl. CPC H02K 7/14; H05K 7/005

(57) ABSTRACT

An electrical appliance assembly includes at least two electric operating modules and a connector. Each of the modules has a housing having a space defined therein, two openings in communication with the space, and blocks protruding from an edge defining the openings; a holder securely received in the housing and capable of holding an electrically drivable device. The connector has grooves and cutouts defined on a peripheral thereof and in communication with each other. The blocks on at least two electric operating modules are passable through the corresponding cutouts and can be slid into the corresponding grooves so as to selectively connect or detach the at least two electric operating modules and the connector.

### BACKGROUND OF THE INVENTION

1. Field of the Invention

The present invention is related to a sectioned electrical appliance assembly, and in particular to an appliance which is a selective combination of modules including heater, illuminator and/or motor depending on the use purpose. The modules can be directly or indirectly assembled. The module(s) can be replaced in part if the module(s) is/are disabled after being used repeatedly without affecting other workable parts. That means, each module in the appliance assembly are independent and cooperatable with other modules, even further with additional attachments, to fulfill specific applications which are stated in the following detailed descriptions.

2. The Prior Art

Home electrical appliances of medium and small size have played an important role in home living, because functions of these appliances bring living convenience, especially illumination and temperature control that are the most important for living environment. Popular electrical appliances of small size include electric toothbrush, electrical razor, flashlight, lamp, water heater kettle, irons, air heater and etc., and each of them works independently. Despite these electric appliances having different functions, however in the simplest condition of that, the driving core of the appliances can be a motor, a heater, a illuminator or their combinations driven by electric power.

Specifically, the appliance is consisted of at least one driving core (except power supply) and other attachments and circuits that driven by the core. For instance, an electric toothbrush is consisted of a motor as its driving core, a transmission mechanism driven by the motor and a brush head driven by the mechanical structure. For another instance, a flashlight is consisted of an LED device as its main driving core and an optical system for guiding and adjusting the light. In order to satisfy all the demands of home living, electrical appliances with different kinds must be completed even some of them are not used quite often.

With regard to repair of appliance, a conventional way is returning the disabled appliance back to the factory or to the specialized repairing department, because most current appliances are not designed to provide convenient assembly structure and conveniently purchased repairing elements for user repair. On the other hand, without the convenient assembly structure, some of the workable parts in the appliance will possibly be damaged during the detachment process, and often scrapping the entire appliance.

### SUMMARY OF THE INVENTION

The objective of the present invention is to provide a sectioned electrical appliance assembly which is, namely, assembled by pristine modules working with various operations, and the modules are capable of coupling to other attachments to perform specific functions. When the module(s) of the sectioned appliance is/are disabled, it can be easily replaced or repaired without damaging the other adjacent part(s) of the electric appliance due to the independency of the modules.

In order to achieve the aforementioned objective, the electrical appliance assembly of the present invention includes at least two electric operating modules and a connector, wherein each of the modules has a housing having a space defined therein, two openings communicating with the space and blocks protruding from an edge defining the openings; and a holder securely received in the housing and capable of holding an electrically drivable device. The connector having grooves and cutouts defined on a peripheral thereof and mutually communicating with each other. The blocks of the at least two electric operating modules are passable through the corresponding cutouts and slidable into the corresponding grooves so as to selectively connect or detach the at least two electric operating modules.

The electrically drivable device can be a motor, a bulb, a heater or other available devices.

Accordingly, each electric operating module can be served as a rotating module, an illuminating module or air/liquid heating module depending on what device installed in the holder. As named, the appliance assembly is a combination of different operating modules through the connector(s), and provides the specific function(s) according to the application purpose. And because each operating modules is an independent unit, every module within the appliance can be replaced without damaging its adjacent parts, just as convenient as light bulb replacing.

### BRIEF DESCRIPTION OF THE DRAWINGS

The invention, as well as its many advantages, may be further understood by the following detailed description and drawings in which:

FIGS. 1A-1C are perspective views and a plane view of a rotating module in accordance with a preferred embodiment of the present invention;

FIGS. 2A-2B are perspective views of an illuminating module in accordance with a preferred embodiment of the present invention;

FIGS. 3A-3B are perspective views of an air heating module in accordance with a preferred embodiment of the present invention;

FIGS. 4A-4B are perspective views of a liquid heating module in accordance with a preferred embodiment of the present invention;

FIGS. 5A-5B are perspective views of a warming module in accordance with a preferred embodiment of the present invention;

FIG. 6 is a perspective view of a connector in accordance with a preferred embodiment of the present invention;

FIGS. 7-11 are exploded views of the modules respectively illustrated in FIGS. 1A, 2A, 3A, 4A and 5A;

FIG. 12 is an application of the sectioned electrical appliance assembly in accordance with the preferred embodiment of the present invention; and

FIG. 13 is another application of the sectioned electrical appliance assembly in accordance with the preferred embodiment of the present invention.

### DETAILED DESCRIPTION OF THE INVENTION

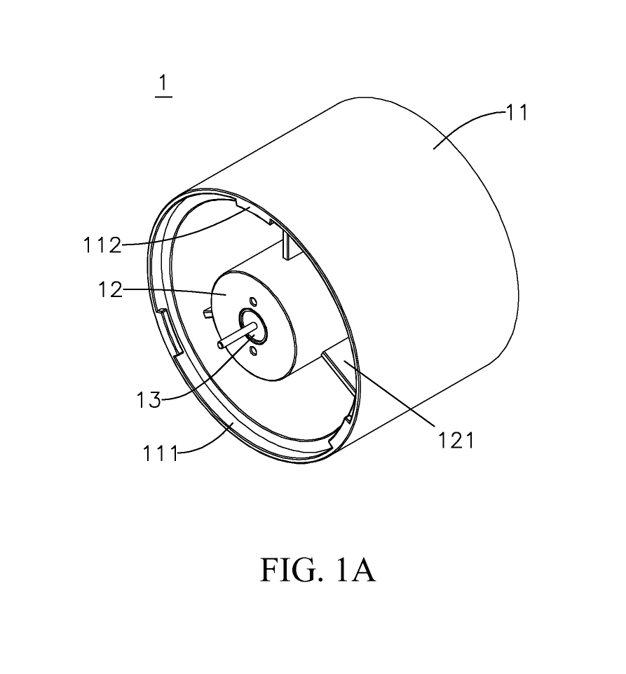

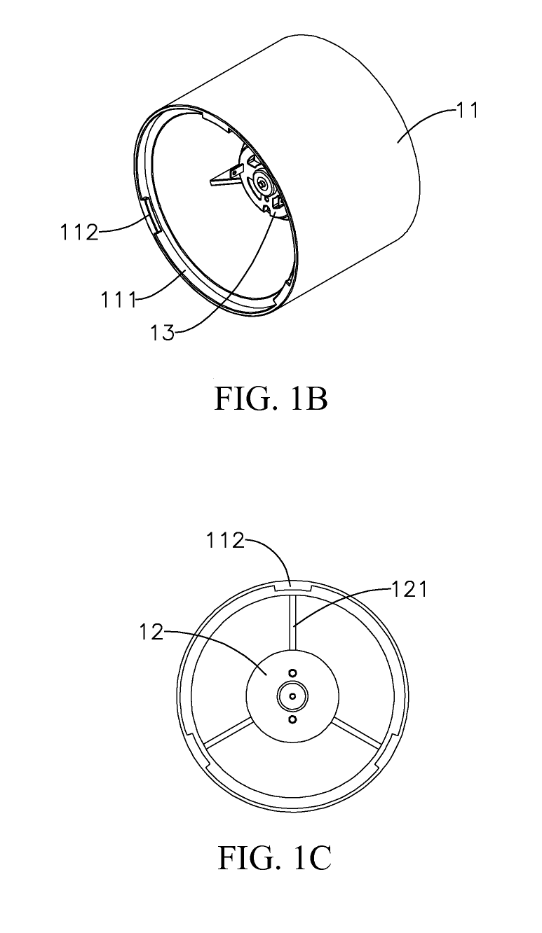

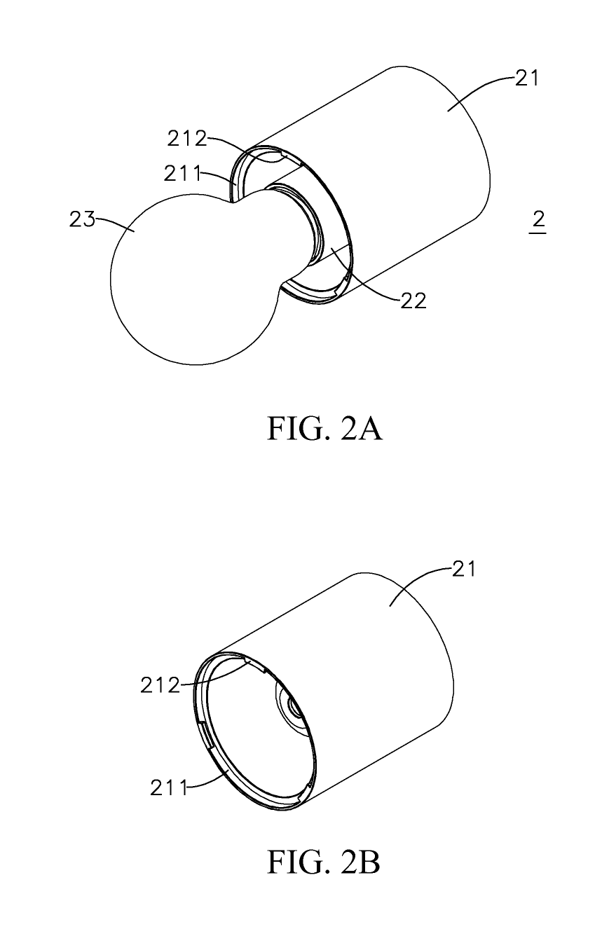

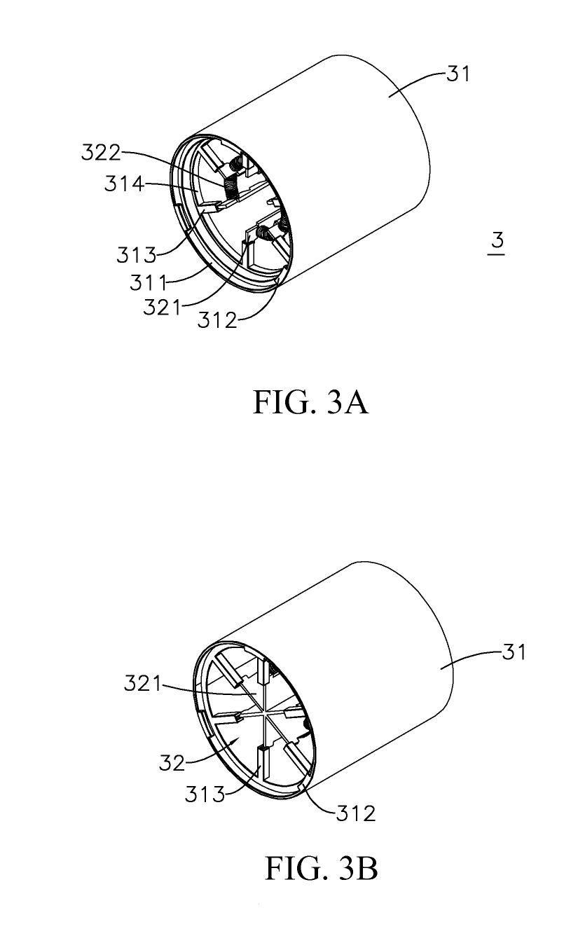

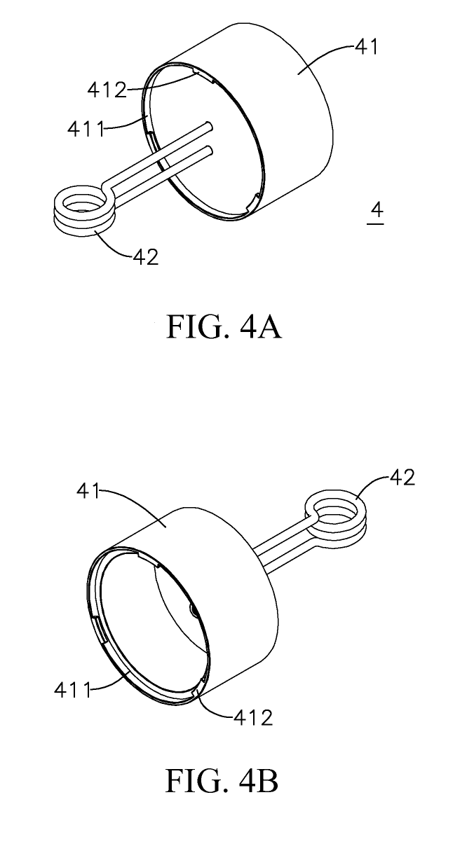

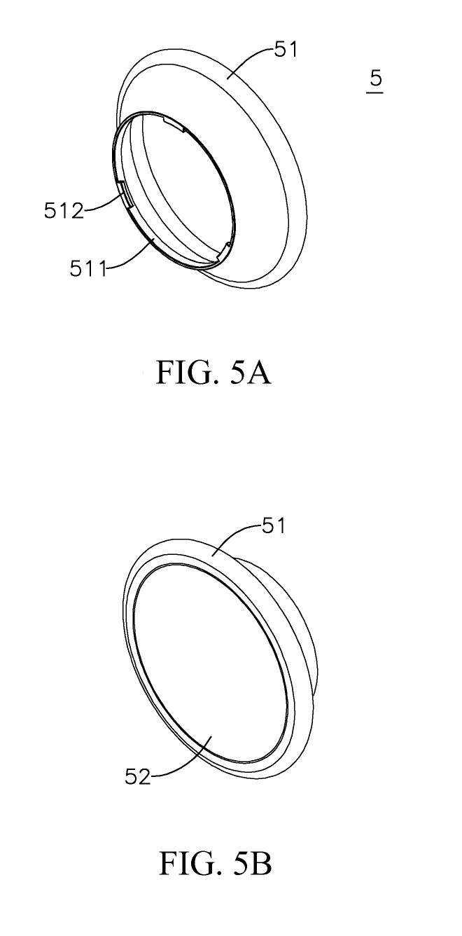

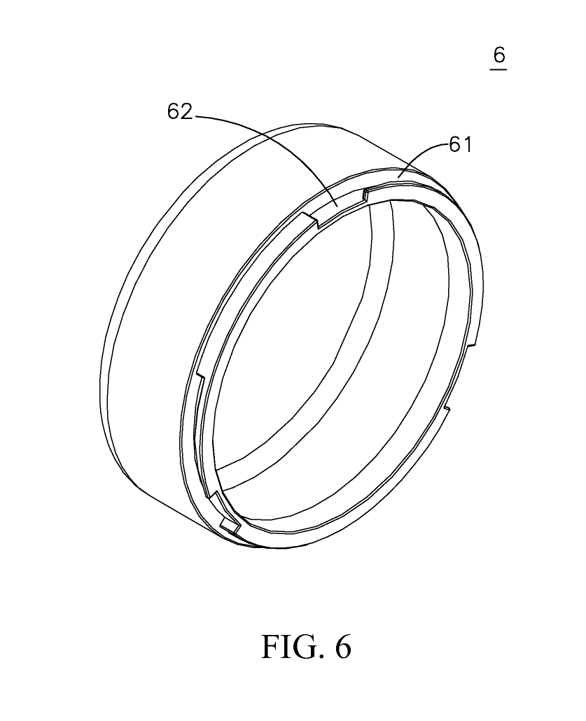

With reference to FIGS. 1A-5B, a sectioned electrical appliance assembly constructed in accordance with a preferred embodiment of the present invention has a rotating module 1(as shown in FIGS. 1A-1C), an illuminating module 2 (as shown in FIGS. 2A-2B), an air heating module 3 (as shown in FIGS. 3A-3B), a liquid heating module 4 (as shown in FIGS. 4A-4B) and a warming module 5 (as shown in FIGS. 5A-5B). The modules 1-5 can be selectively assembled together to meet different application purposes, or can be assembled through a connector 6 as illustrated in FIG. 6. The connection provided by the connector 6 is illustrated later.

Referring to FIGS. 1A-1C, the rotating module 1 has a housing 11, a container 12 and a motor 13 securely received in the container 12. The housing 11 can be a sleeve having flanges 111 of thinner thickness formed on both openings thereof, and the inner wall of each flange 111 has a plurality of blocks 112 protruding inward. The container 12 securely positioned in the housing 11 by supports 121 connecting the housing 11 and the container 12. The motor 13 can be securely received in the container 12 by a conventional manner, for example, by threaded. The size of the container 12 can be designed to fit the motor's occupation. The motor 13 can be a DC motor, AC motor, a step motor or others that can provide rotation.

The motor 13 can be locked and held stably in the container 2, to prevent it from turning loose during application.

Referring FIGS. 2A-2B, the illuminating module 2 has a housing 21, a container 22 and an illuminator 23 (for example, a light bulb). However, the connection of the housing 21 and the container 22 are the same as the foregoing housing 11 and container 12 of the rotating module 1, and the only different is the depth of the container 22 of the illuminating module 2 that is designed for purpose of installing the illuminator 23. The housing 21 has flanges 211 respectively formed on the two openings thereof and blocks 212 protruded from the inner wall of the flanges 211. Also, the container 22 securely positioned inside the housing 21 by supports (not shown in FIGS. 2A-2B) as the foregoing supports 121. The interior of the container 22 can configure a bulb holder (not shown) to provide electrical connection with the bulb which can be substituted by another one.

Referring to FIGS. 3A-3B, the air heating module 3 has a housing 31 and a heater 32, wherein the housing 31 has flanges 311 and a plurality of blocks 312, whose configuration are identical with foregoing structure, and therefore the description thereof is omitted. It is noted, the housing 31 of the air heating module 3 further has supporting bars 313 and a ring 314 detachable to the housing 31, a subset of the supporting bars 313 is extending from the ring 314 as illustrated in FIG. 3A, and another subset of the supporting bars 313 is extending from the inner wall of the housing 31, as illustrated in FIG. 3B. Each of the supporting bars 313 has a slit (not numbered) defined on a side thereof. The heater 32 is consisted of a frame 321 and heating coils 322 arranged in the frame 321 by a conventional manner, wherein the frame 321 is constructed of plates and the heating coils 322 are securely received in the space between the plates. The plates of the frame 321 can be received in the corresponding slits of the supporting bars 313 to hold the heater 32 in the housing 31. Power supply wire(s) can extend through the hollows of the housing 31 and connect with the heater 32 to be powered, and heating the air around.

Referring to FIGS. 4A-4B, the liquid heating module 4 has a housing 41 and an electrical heat rod 42 extending outwardly from the housing 41. The housing 41 has flanges 411 and a plurality of blocks 412, whose configurations are identical with foregoing structure, and therefore the description thereof is omitted. The electrical heat rod 42 can be designed as different shapes which are not limited by the drawings. Power supply wire(s) can extend through the hollows of the housing 41 and connect with the electrical heat rod 42 to be powered, to heat up the rod.

Referring to FIGS. 5A-5B, the warming module 5 has a hollow basin structure 51 having two openings, and a thermal conductor 52 (such as metal) securely mounted on an edge defining the opening of the warming module 5. The housing 51 has a flange 511 and blocks 512, whose configurations are identical with foregoing structure, and therefore the description is omitted. The thermal conductor 52 further has an electrical heater 53 (with reference to FIG. 11) securely attached to an inside surface of the thermal conductor 52 and capable of generating heat propagating through the thermal conductor 52 to provide a warn surface.

Referring to FIG. 6, the connector 6 is provided in accordance with the invention is a ring having grooves 61 (there are two as shown in FIG. 6) and cutouts 62 both defined on the peripheral thereof, wherein the cutouts 62 communicate with the corresponding grooves 61, so as to allow the corresponding blocks of the foregoing modules 1, 2, 3, 4 and 5 passing through and sliding into the grooves 61 to connect any one or any two modules. However, according to the different application purposes, the connector 6 can be designed as other aspects, which are then described in the following paragraphs but not a limitation of the invention.

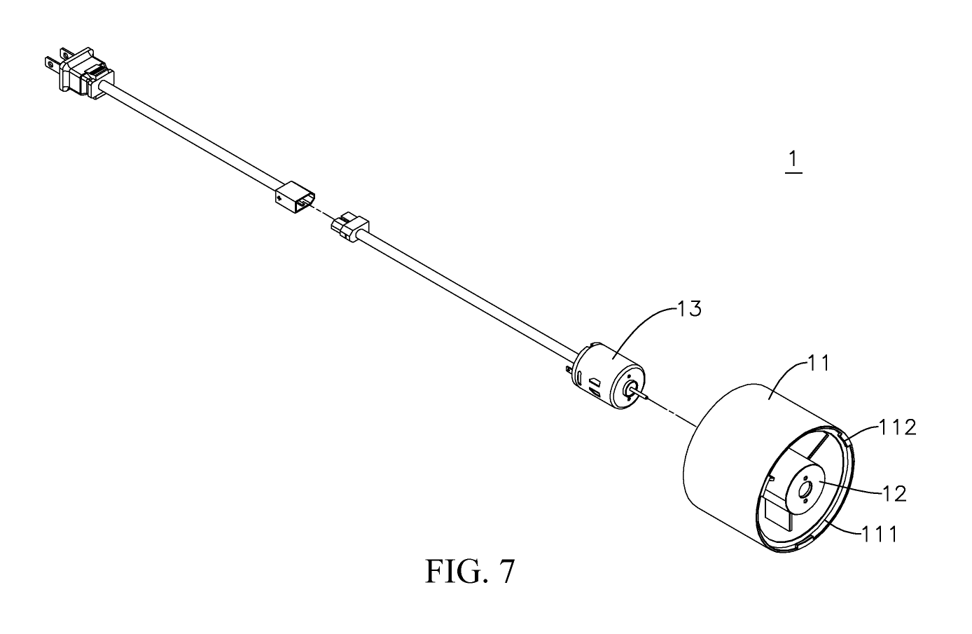

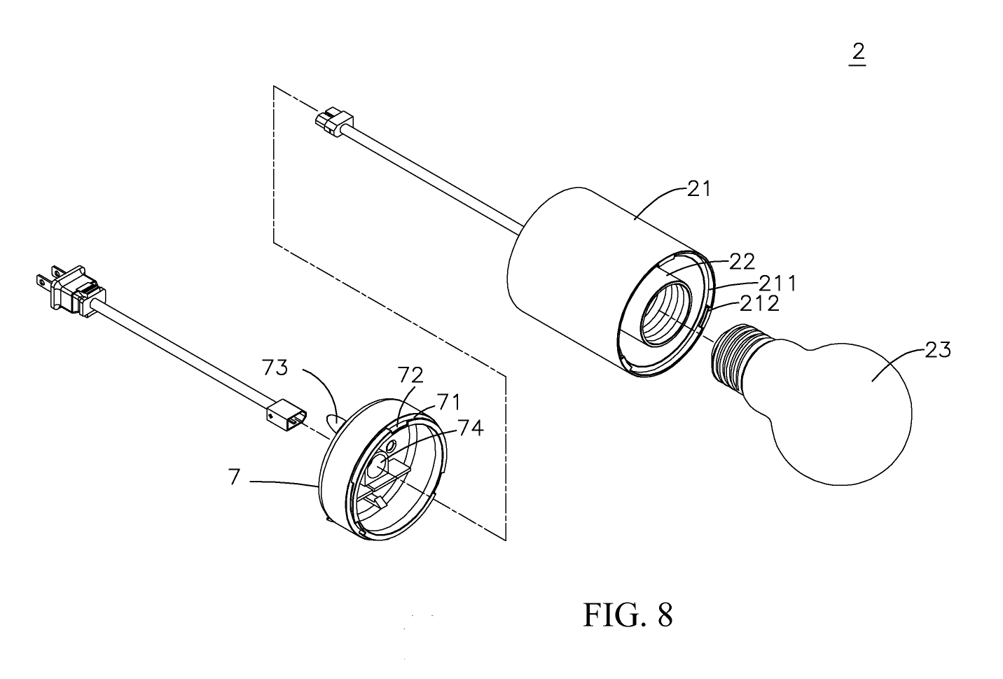

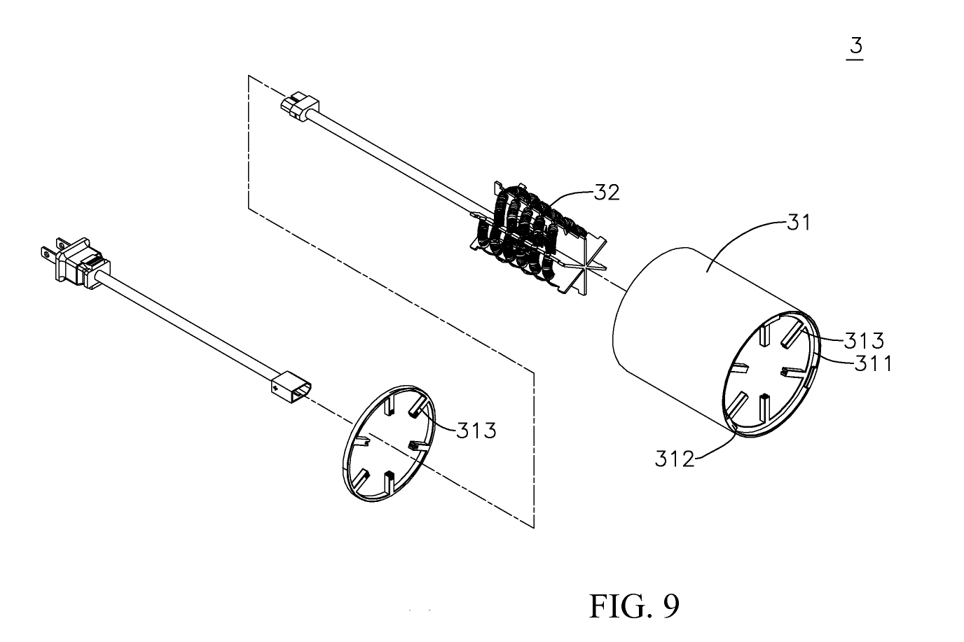

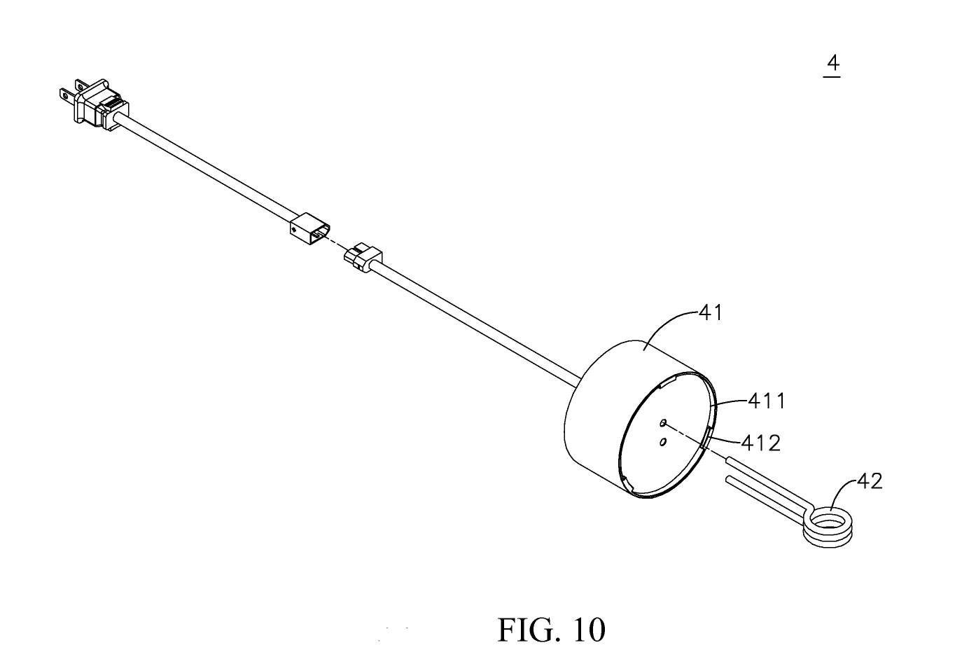

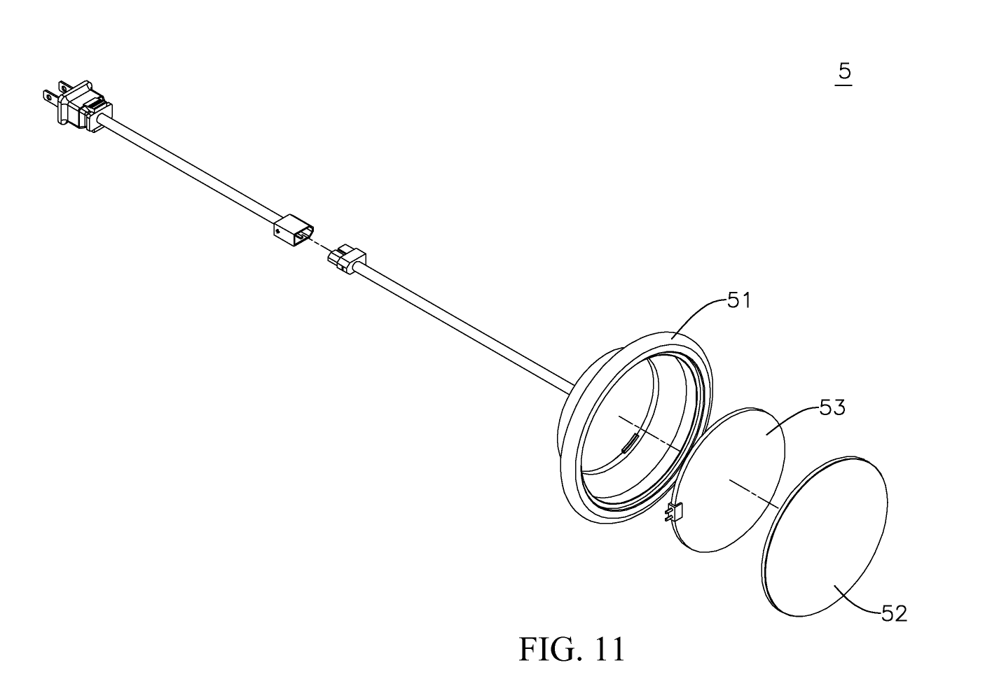

With reference to FIGS. 7-11, which illustrates detachment of the foregoing modules 1, 2, 3, 4 and 5 in accordance with the preferred embodiment of the present invention. FIG. 11 clearly shows the electrical heater 53 of the warming module 5 is contained inside the hollow basin 51. Referring to FIG. 8, the illuminating module 2 can connect with a base 7 having a corresponding groove 71, blocks 72 (just as the same configuration of the connector 6), supporting legs 73 and a through hole 74 provided for power connection, so that the illuminating module 2 is then assembled and served as a desk lamp. The connection of the power supply is well-known in the art, so the illustration thereof is omitted.

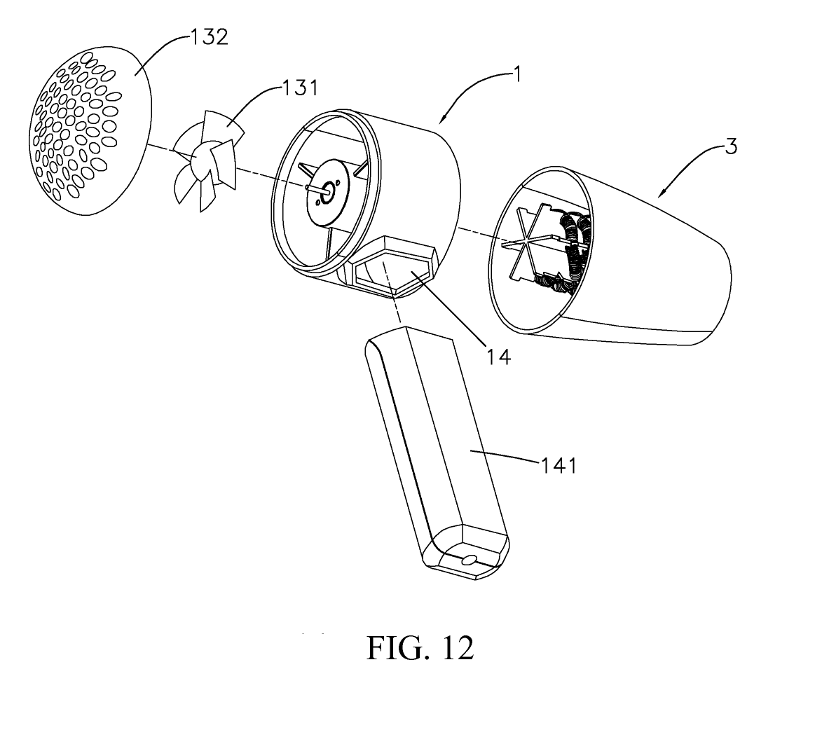

With reference to FIG. 12, an application illustrates a hair dryer which is assembled including the rotating module 1 and the air heating module 3, both are mentioned in previous paragraphs. The rotating module 1 is connectable with the air heating module 3 through the aforementioned connector 6 (not shown in FIG. 12). The motor 13 connects to a fan 131, and the rotating module 1 connects with a fan cover 132 by the same manner that blocks penetrate the corresponding cutouts and then slide into the groove. Thus, when the rotating module 1 and the air heating module 3 are powered at the same time, hot wind is then generated. It is noted, the structure of the housing of the foregoing modules 1, 2, 3, 4 and 5 can be variable, which depends on the use purpose. For example, in FIG. 12, the housing of the rotating module 1 further has a recessed installation hole 14 defined on a peripheral of the housing for receiving an end of a handle 141, and one side of the housing of the air heating module 3 gradually reduces to radius and converges toward to an opening that served as dryer's outlet.

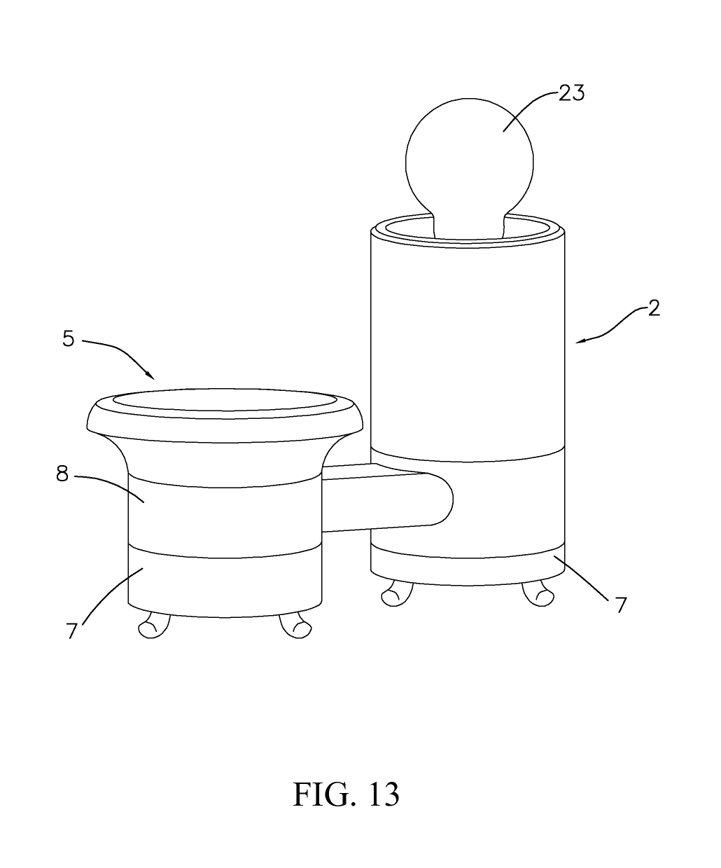

With reference to FIG. 13, another application illustrates a combination of a cup warmer and a desk lamp. It is noted here, a double connector 8 consisted of two connector 6 provides a connection to the illuminating module 2, the warming module 5 and two bases 7, and thus creating a desktop appliance that can offer illumination to desk works and can warm hot drink at the same time, especially suitable for reading time.

However, except the illustrated description and drawings in the present invention, the modules 1, 2, 3, 4 and 5 can be selectively assembled a specific appliance to meet user's need, and the wiring for power supply can be united if the working voltage of all modules are the same, or can be independent if the working voltage of all modules are different. It is noted, the connector 6 and the base 7 illustrated in the preferred embodiment of the invention can be changed into other variations but having the detachable configuration like the grooves, the cutouts and the corresponding blocks. Most importantly, the present invention has much more convenience that user can easily replace the disable element(s) of each module, such as the motor, the bulb or the housing, without damaging other workable elements.

Many changes and modifications in the above described embodiment of the invention are able to, of course, be carried out without departing from the scope thereof. Accordingly, to promote the progress in science and the useful arts, the invention is disclosed and is intended to be limited only by the scope of the invention.

What is claimed is:

1. An electrical appliance assembly comprising:
at least two electrical operating modules, each of that comprising:
a housing having a space defined therein, two openings communicating with the space and blocks protruding from an edge defining the openings;
a holder securely received in the housing and capable of selectively holding an electrically drivable device; and
a connector, having grooves and cutouts defined on a periphery surface thereof and mutually communicating with each other,
wherein the blocks of the at least two electrical operating modules are passed through the corresponding cutouts and slid into the corresponding grooves so as to selectively connect or detach the at least two electrical operating modules and the connector.

2. The electrical appliance assembly as claimed in claim 1, wherein the housing is a sleeve.

3. The electrical appliance assembly as claimed in claim 1, wherein the holder has supports extending from a periphery surface thereof and securely connecting to an inner wall of the housing.

4. The electrical appliance assembly as claimed in claim 2, wherein the holder has support extending from a peripheral thereof and securely connecting to an inner wall of the housing.

5. The electrical appliance assembly as claimed in claim 2, wherein the sleeve has flanges extending from an edge defining the openings, and the blocks are protruding from an inner wall of each of the flanges.

6. The electrical appliance assembly as claimed in claim 5, wherein the electrically drivable device is selected from a group consisting of a motor, a bulb and a heater.

7. An electrical appliance assembly, comprising:
a rotating module having a housing and a motor securely received in the housing of the rotating module;
an illuminating module having a housing and a bulb securely received in the housing of the illuminating module;
an air heating module having a housing and heating coils securely received in the housing of the air heating module;
a liquid heating module having a housing and an electrical heating rod extending from one side of the housing of the liquid heating module; and
a warming module having a hollow basin, an electrical heater securely received in the housing of the warming module and a thermal conductor attached to one side of the electrical heater,
said modules are slidingly connectable to be selectively assembled, and slidingly detachable to be selectively substituted.

8. The appliance assembly as claimed in claim 7, wherein the housing of each of the modules being a sleeve.

9. The appliance assembly as claimed in claim 7, wherein the housing of each of the modules has a holder contained inside the housing and having supports extending from a peripheral of the holder to connect to a inner wall of the housing.

10. The wheel assembly as claimed in claim 8, wherein the sleeve of each of the modules has a holder contained inside the sleeve and having supports extending from a peripheral of the holder to connect to a inner wall of the sleeve.

11. The appliance assembly as claimed in claim 7, wherein the rotating module, the illuminating module, the air heating module, the liquid heating module and the warming module are selectively coupled via an intermediary connector.

12. The appliance assembly as claimed in claim 11, wherein the housing of each of the modules has blocks protruding from an inner wall thereof.

13. The appliance assembly as claimed in claim 12, wherein the intermediary connector has grooves and cutouts defined on a peripheral thereof, and the cutouts communicate with the grooves to correspond to the blocks that pass through the corresponding cutouts and
slide into the grooves to couple the modules.
